(19) United States
(12) Patent Application Publication
(10) Pub. No.: US 2026/0100505 A1
(43) Pub. Date: Apr. 9, 2026

(54) WIRELESS COMMUNICATION DEVICE AND METHOD FOR COMPENSATING NONLINEAR DISTORTION OF WIRELESS COMMUNICATION DEVICE

(71) Applicant: Realtek Semiconductor Corp., HsinChu (TW)

(72) Inventor: Chih-Chieh Wang, HsinChu (TW)

(73) Assignee: Realtek Semiconductor Corp., HsinChu (TW)

(21) Appl. No.: 19/352,412

(22) Filed: Oct. 7, 2025

(30) Foreign Application Priority Data
Oct. 8, 2024 (TW) 113138213

(51) Int. Cl. H01Q 3/38; H01Q 23/00; H03F 1/32

(52) U.S. Cl. CPC H01Q 3/38; H01Q 23/00; H03F 1/3241; H03F 2200/451

(57) ABSTRACT

A wireless communication device and a method for compensating nonlinear distortion of a wireless communication device are provided. The wireless communication device includes a transmitting (TX) baseband circuit, an amplitude modulation (AM) circuit, a phase modulation (PM) circuit, a power amplifier (PA), a calculation circuit and a compensation circuit. The TX baseband circuit outputs a TX signal to make the AM circuit and the PM circuit generate an AM signal and a PM signal, respectively. The PA takes the AM signal as a supply voltage and generates an output signal according to the PM signal. The calculation circuit estimates a delay skew between the AM signal and the PM signal according to a detection result of the output signal to generate an estimation result, and the compensation circuit compensates the AM signal or the PM signal according to the estimation result, in order to reduce the delay skew.

### BACKGROUND OF THE INVENTION

### 1. Field of the Invention

The present invention is related to compensation of nonlinear distortion, and more particularly, to a wireless communication device and a method for compensating nonlinear distortion of the wireless communication device.

### 2. Description of the Prior Art

When designing wireless communication modulation transceivers, a polar transmitter architecture can achieve significant improvements in power saving compared to an in-phase/quadrature (I/Q) modulation architecture, and more particularly, can reduce performance requirements of a power amplifier (PA) at a specific target output power. In addition to nonlinear distortion related to signal swings caused by the PA, however, there are other factors in the polar coordinate transmitter that cause nonlinearity in an output signal. Although related arts have proposed analysis methods to determine a relationship between these factors and the nonlinearity of the output signal, these methods typically utilize external signal generators and spectrum analyzers to obtain measurement results, rather than verification based on a complete transmitter architecture.

In addition, as nonlinear distortion of the output signal of the transmitter can be caused by various different factors, and the related arts are unable to effectively separate effects caused by these factors, compensation operations after the analysis fail to achieve an optimal result. Thus, there is a need for a novel architecture and an associated method, which can solve the problems of the related art without introducing any side effect or in a way that is less likely to introduce side effects.

### SUMMARY OF THE INVENTION

An objective of the present invention is to provide a wireless communication device and a method for compensating nonlinear distortion of the wireless communication device, in order to effectively separate various factors which cause the nonlinear distortion and to accordingly perform linearity compensation.

At least one embodiment of the present invention provides a wireless communication device. The wireless communication device comprises a transmitting (TX) baseband circuit, an amplitude modulation (AM) circuit, a phase modulation (PM) circuit, a power amplifier (PA), a delay calculation circuit and a delay compensation circuit, where the PA is coupled to the AM circuit and the PM circuit, and the delay compensation circuit is coupled to the TX baseband circuit and the delay calculation circuit. The TX baseband circuit is configured to output a TX signal, the AM circuit is configured to generate an AM output signal according to an AM TX signal of the TX signal, and the PM circuit is configured to generate a PM output signal according to a PM TX signal of the TX signal. In addition, the PA is configured to take the AM output signal as a supply voltage and generate an output signal according to the PM output signal. More particularly, the delay calculation circuit is configured to estimate a delay skew between the AM output signal and the PM output signal according to a detection result of the output signal to generate an estimation result, and the delay compensation circuit is configured to compensate the AM output signal or the PM output signal according to the estimation result, in order to reduce the delay skew.

At least one embodiment of the present invention provides a method for compensating nonlinear distortion of a wireless communication device. The method comprises: utilizing a TX baseband circuit of the wireless communication device to output a TX signal; utilizing an AM circuit of the wireless communication device to generate an AM output signal according to an AM TX signal of the TX signal; utilizing a PM circuit of the wireless communication device to generate a PM output signal according to a PM TX signal of the TX signal; utilizing a PA of the wireless communication device to take the AM output signal as a supply voltage and generate an output signal according to the PM output signal; utilizing a delay calculation circuit of the wireless communication device to estimate a delay skew between the AM output signal and the PM output signal according to a detection result of the output signal to generate an estimation result; and utilizing a delay compensation circuit of the wireless communication device to compensate the AM output signal or the PM output signal according to the estimation result, in order to reduce the delay skew.

The wireless communication device and the method provided by the embodiments of the present invention can estimate the delay skew between an AM path and a PM path according to the detection result of the output signal such as a third-order intermodulation distortion (IMD3) value, and accordingly compensate the AM path or the PM path to reduce the delay skew. In addition, the embodiments of the present invention will not greatly increase additional costs. Thus, the present invention can improve performance of nonlinear distortion compensation without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a wireless communication device according to an embodiment of the present invention.

FIG. 2 is a diagram illustrating a relationship between a delay skew and a third-order intermodulation distortion value under different frequency intervals of a two-tone test according to an embodiment of the present invention.

FIG. 3 is a diagram illustrating a main signal and a third-order modulation signal on a spectrum according to an embodiment of the present invention.

FIG. 4 is a diagram illustrating a wireless communication device according to an embodiment of the present invention.

FIG. 5 is a diagram illustrating a wireless communication device according to an embodiment of the present invention.

FIG. 6 is a diagram illustrating a wireless communication device according to an embodiment of the present invention.

FIG. 7 is a diagram illustrating improvements in signal linearity by delay compensation and digital pre-distortion according to an embodiment of the present invention.

FIG. 8 is a diagram illustrating a working flow of a method for compensating nonlinear distortion of a wireless communication device according to an embodiment of the present invention.

### DETAILED DESCRIPTION

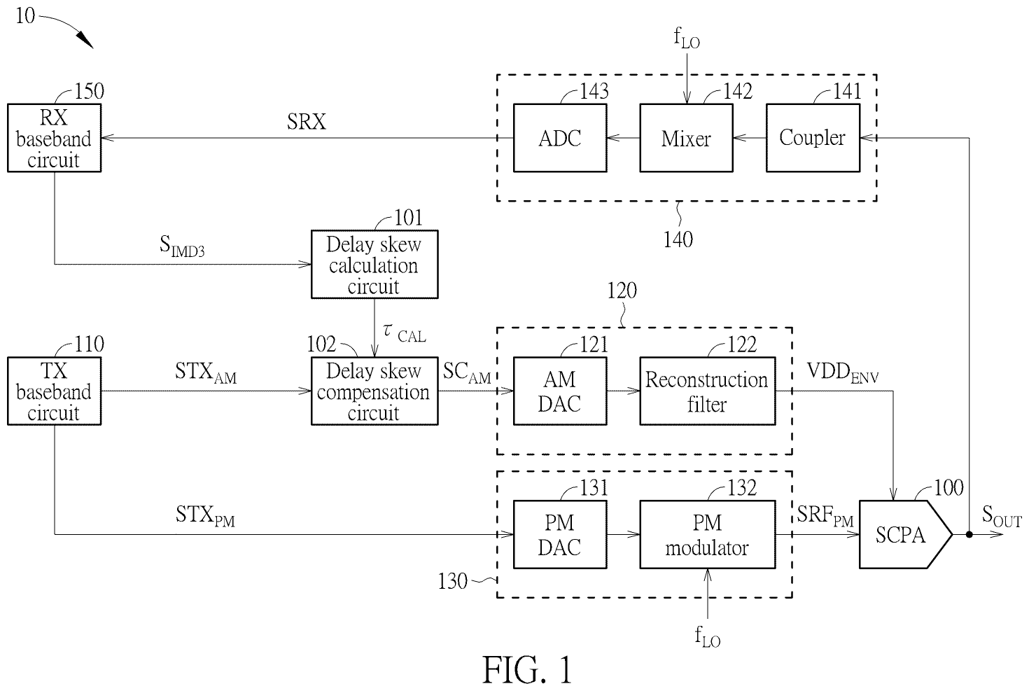

FIG. 1 is a diagram illustrating a wireless communication device 10 according to an embodiment of the present invention, where the wireless communication device 10 may be a polar transmitter or a transceiver comprising the polar transmitter. As shown in FIG. 1, the wireless communication device 10 may comprise a transmitting (TX) baseband circuit 110, an amplitude modulation (AM) circuit 120, a phase modulation (PM) circuit 130, a power amplifier (PA) such as a switched capacitor power amplifier (SCPA) 100, a delay calculation circuit such as a delay skew calculation circuit 101, and a delay compensation circuit such as a delay skew compensation circuit 102, where the SCPA 100 is coupled to the AM circuit 120 and the PM circuit 130, and the delay skew compensation circuit 102 is coupled to the TX baseband circuit 110 and the delay skew calculation circuit 101. In this embodiment, the TX baseband circuit 110 is configured to output a TX signal such as signals STX_{AM} and STX_{PM}, where the signal STX_{AM} may be a TX signal of an AM path under the polar transmitter architecture, and the signal STX_{PM} may be a TX signal of a PM path under the polar transmitter architecture. The AM circuit 120 belongs to the AM path under the polar transmitter architecture, and is configured to generate an AM output signal such as a signal VDD_{ENV} according to an AM TX signal such as a signal STX_{AM} of the TX signal, and the PM circuit 130 belongs to the PM path under the polar transmitter architecture, and is configured to generate a PM output signal such as a signal SRF_{PM} according to a PM TX signal such as a signal STX_{PM} of the TX signal, where the SCPA 100 is configured to take the signal VDD_{ENV} as a supply voltage, and generate an output signal such as a signal S_{OUT} according to the signal SRF_{PM} (e.g. amplifying the signal SRF_{PM} to generate the signal S_{OUT}). In addition, the delay skew calculation circuit 101 is configured to estimate a delay skew between the signal VDD_{ENV} and the signal SRF_{PM} according to a detection result of the signal S_{OUT} to generate an estimation result τ_{CAL}, and the delay skew compensation circuit 102 is configured to compensate the signal VDD_{ENV} or the signal SRF_{PM} according to the estimation result τ_{CAL}, in order to reduce the delay skew.

The delay skew between the signal VDD_{ENV} and the signal SRF_{PM} may be regarded as a delay skew between the AM path and the PM path under the polar transmitter architecture, which may be referred to as an AM-PM delay. The wireless communication device 10 divides the signal to be transmitted into an AM component (e.g. the signal STX_{AM}) and a PM component (e.g. the signal STX_{PM}) for being respectively processed via the AM path and the PM path. When signals on the AM path and the PM path are not synchronous (e.g. when signal delays of the AM path and the PM path are not identical and therefore introduce the AM-PM delay mentioned above), the signal S_{OUT} output from the SCPA 100 may have nonlinear distortion. Thus, the delay skew calculation circuit 101 may estimate the delay skew according to an index value of the signal S_{OUT} (e.g. the detection result), to enable the delay skew compensation circuit 102 in order to properly adjust the signal delays of the AM path or the PM path, thereby synchronizing the signals on the AM path and the PM path.

In this embodiment, the delay skew compensation circuit 102 is coupled between the TX baseband circuit 110 and the AM circuit 120, where the delay skew compensation circuit 102 may perform delay skew control on the signal STX_{AM} according to the estimation result ICAL to generate a compensated AM TX signal such as a signal SC_{AM}, and the AM circuit 120 may generate the signal VDD_{ENV} according to the signal SC_{AM}. For example, the delay skew compensation circuit 102 may utilize a programmable delay unit therein to receive the signal STX_{AM} to output the signal SC_{AM} with a programmable delay, thereby achieving the purpose of performing delay control on the signal VDD_{ENV}. Under the architecture shown in FIG. 1, an AM digital-to-analog converter (DAC) 121 within the AM circuit 120 may perform a digital-to-analog conversion on the signal SC_{AM} output from the delay skew compensation circuit 102, and a reconstruction filter 122 within the AM circuit 120 may perform filtering on an output of the AM DAC 121 to generate the signal VDD_{ENV}. In addition, a PM DAC 131 within the PM circuit 130 may perform a digital-to-analog conversion on the signal STX_{PM}, and a PM modulator 132 within the PM circuit 130 may perform up-conversion on an output of PM DAC 131 based on the local oscillation (LO) frequency f_{LO} to generate the signal SRF_{PM}.

In this embodiment, the wireless communication device 10 may further comprise a receiving (RX) circuit 140 and an RX baseband circuit 150, where the RX circuit 140 is coupled to the SCPA 100, and the RX baseband circuit 150 is coupled to the RX circuit 140 and the delay skew calculation circuit 101. The RX circuit 140 is configured to receive the signal S_{OUT} from the SCPA 100 and generate an RX signal such as the signal SRX according to the signal S_{OUT}. For example, a coupler 141 within the RX circuit 140 may receive the signal S_{OUT} and output an alternating current (AC) component of the signal S_{OUT}, a mixer 142 within the RX circuit 140 may perform a down-conversion on an output of the coupler 141 based on the LO frequency f_{LO}, and an analog-to-digital converter (ADC) 143 within the RX circuit 140 may perform an analog-to-digital conversion on an output of the mixer 142 to generate the signal SRX. In addition, the RX baseband circuit 150 is configured to generate the detection result of the signal S_{OUT} according to the signal SRX. For example, the detection result may comprise a third-order intermodulation distortion (IMD3) value of the signal S_{OUT} such as a signal S_{IMD3}, and the delay skew calculation circuit 101 may perform calculation according to the signal S_{IMD3} to estimate the delay skew between the signal VDD_{ENV} and the signal SRF_{PM}, thereby outputting the estimation result τ_{CAL}.

The AM component and the PM component of the signal S_{OUT} may be represented by the signal S_{AM} and the signal S_{PM}, and the signal S_{AM} and the signal S_{PM} may be expressed based on a time parameter t as follows:

$${S}_{AM} = {A}_{OUT} \times \vert cos ( {ω}_{m} t ) \vert$$

$${S}_{PM} = Sgn ( cos ( {ω}_{m} ( t + τ ) ) ) = C ( {ω}_{m} + τ )$$

Note that A_{OUT}=A_{IN}×G_{SCPA}, A_{IN} may represent an amplitude of the signal VDD_{ENV}, G_{SCPA} may represent a gain of the SCPA 100, ωₘ may represent a frequency of a two-tone test (which may correspond to a frequency interval of the two-tone test), t may represent the AM-PM delay (e.g. the delay skew between the signal VDD_{ENV} and the signal SRF_{PM}), and Sgn( ) may represent a PM function. In addition, Sgn(cos(ωₘ(t+τ))) may be expressed by C(ωₘ+τ) for brevity. Thus, the signal S_{OUT} may be expressed by S_{AM}×S_{PM} as follows:

$$\begin{matrix}{S}_{AM} \times {S}_{PM} & = {A}_{OUT} \times \vert cos ( {ω}_{m} t ) \vert \times C ( {ω}_{m} + τ ) = {A}_{OUT} \times \vert cos ( {ω}_{m} t ) \vert \times [ C ( {ω}_{m} + τ ) - C ( {ω}_{m} ) + C ( {ω}_{m} ) ] \\ & = {A}_{OUT} \times cos ( {ω}_{m} t ) + {A}_{OUT} \times \vert cos ( {ω}_{m} t ) \vert \times [ C ( {ω}_{m} + τ ) - C ( {ω}_{m} ) ] \\ & = {A}_{OUT} \times cos ( {ω}_{m} t ) + {A}_{OUT} \times u ( {ω}_{m} t )\end{matrix}$$

Note that A_{OUT}×cos(ωₘt) is a main signal, and A_{OUT}×|cos(ωₘt)|×[C(ωₘ+τ)−C(ωₘ)] is an intermodulation signal, where |cos(ωₘt)|×[C(ωₘ+τ)−C(ωₘ)] may be simplified as u(ωₘt), and the expression of the intermodulation signal is therefore simplified as A_{OUT}×u(ωₘt). Overall intermodulation distortion IMD_{TOTAL} may be expressed as follows:

$$I M {D}_{TOTAL} = \vert \frac{{A}_{OUT} \times u ( {ω}_{m} t )}{{A}_{OUT} \times cos ( {ω}_{m} t )} \vert$$

Note that a relationship between the IMD3 value and the AM-PM delay τ may be obtained by derivation of the overall intermodulation distortion IMD_{TOTAL} based on a Taylor expansion. In detail, coefficients {aₖ, bₖ} of the Taylor expansion may be expressed as follows:

$${a}_{k} = - \frac{2}{π} [ \frac{1 - cos ( k + 1 ) τ}{k + 1} + \frac{cos ( k - 1 ) τ - 1}{k - 1} ]$$

$${b}_{k} = - \frac{2}{π} [ \frac{sin ( k - 1 ) τ}{k - 1} + \frac{sin ( k + 1 ) τ}{k + 1} ]$$

Note that associated coefficients of the IMD3 value such as a₃ and b₃ can be obtained by setting k to be 3, and the relationship between the IMD3 value and the AM-PM delay τ can be further obtained as follows:

$$I M D 3 = \vert {a}_{3} \times cos ( 3 {ω}_{m} t ) + {b}_{3} \times sin ( 3 {ω}_{m} t ) \vert = \frac{2}{π} \times \sqrt{{[ \frac{1 - cos ( 4 ) τ}{4} + \frac{cos ( 2 ) τ - 1}{2} ]}^{2} + {[ \frac{sin ( 2 ) τ}{2} + \frac{sin ( 4 ) τ}{4} ]}^{2}} \qquad ( 4 )$$

Thus, the RX baseband circuit 150 may perform spectrum analysis on the signal SRX to obtain the IMD3 value of the signal SRX (e.g. the IMD3 value of the signal S_{OUT}), and transmit information of the IMD3 value to the delay skew calculation circuit 101 via the signal S_{IMD3}, where the delay skew calculation circuit 101 may perform calculation according to the IMD3 value to estimate the AM-PM delay τ and thereby generate the estimation result τ_{CAL}.

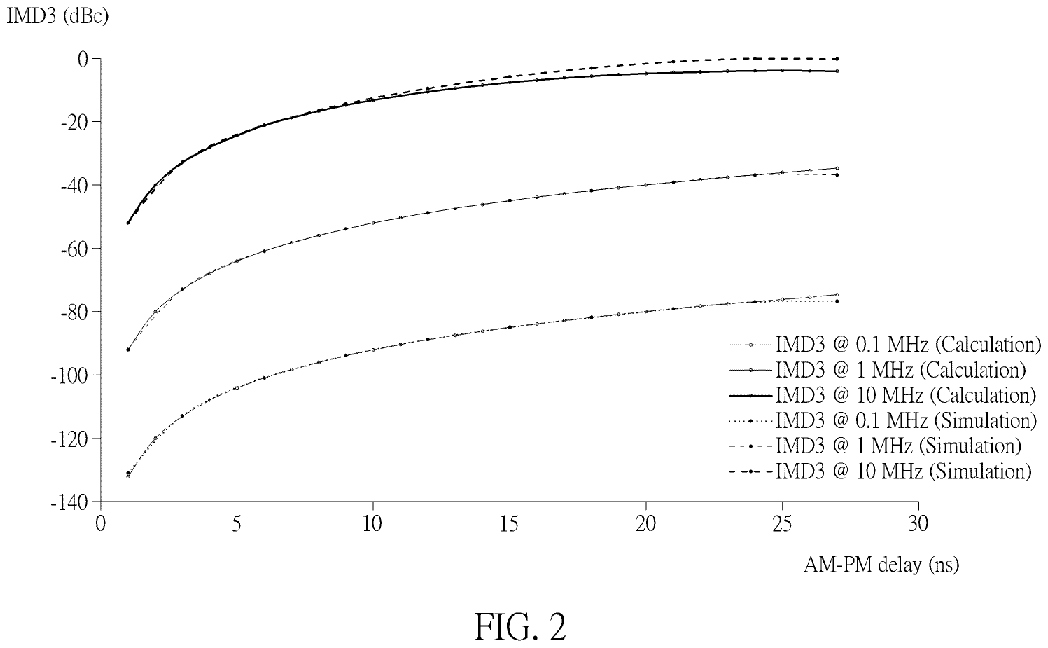

FIG. 2 is a diagram illustrating a relationship between the delay skew (e.g. the AM-PM delay τ) and the IMD3 value under different frequency intervals (e.g. 0.1 MHz, 1 MHz and 10 MHz) of the two-tone test according to an embodiment of the present invention, where FIG. 2 shows curves obtained according to the above calculation and curves obtained by a circuit simulator under various frequency intervals of the two-tone test. As shown in FIG. 2, under various frequency intervals of the two-tone test, the results obtained according to the above calculation substantially match the results obtained by the circuit simulator.

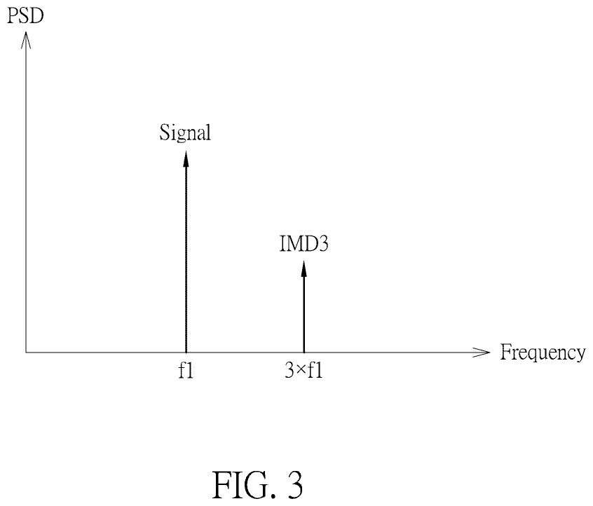

FIG. 3 is a diagram illustrating a main signal (e.g. a signal with a frequency f1) and a third-order intermodulation signal (e.g. a signal with a frequency 3×f1) on a spectrum according to an embodiment of the present invention, where a horizontal axis of FIG. 3 represents the frequency, and a vertical axis of FIG. 3 represents a power spectrum density (PSD). In particular, the RX baseband circuit 150 may calculate power of the main signal and power of the third-order intermodulation signal, and calculate a ratio of their power to obtain the IMD3 value. In some embodiments, the delay skew calculation circuit 101 may perform the above calculation to calculate the AM-PM delay τ according to information of the IMD3 value provided by the RX baseband circuit 150. In some embodiments, the delay skew calculation circuit 101 may record calculation results of the above calculation (e.g. values of the AM-PM delay τ corresponding to respective results of the IMD3 value) in a built-in lookup table in advance, and output a corresponding value of the estimation result τ_{CAL}, according to the lookup table when the signal S_{IMD3} is received.

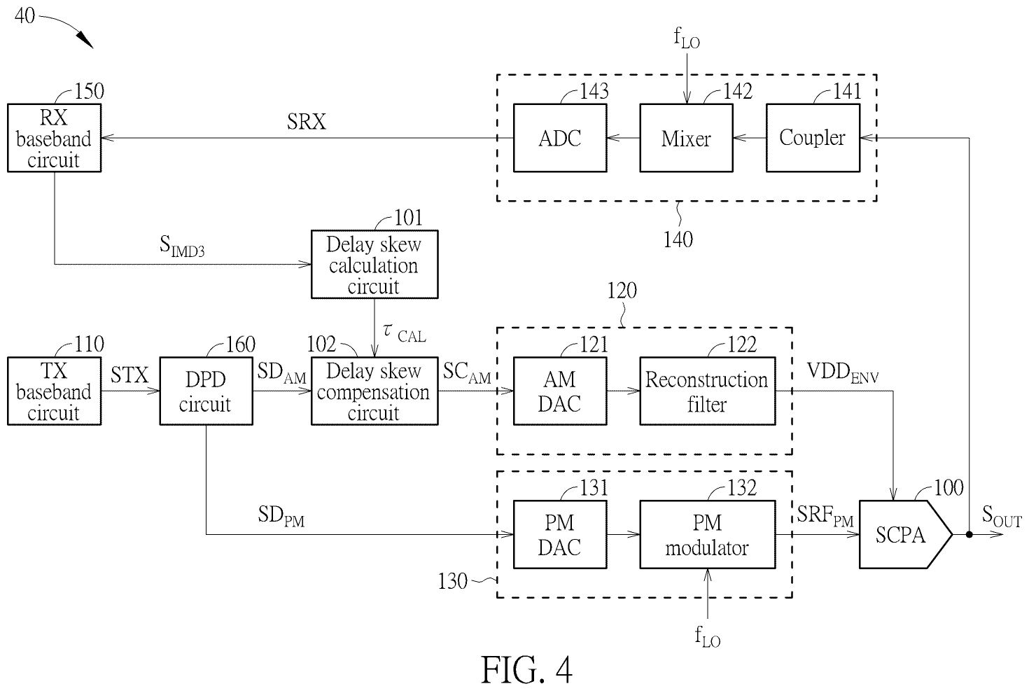

FIG. 4 is a diagram illustrating a wireless communication device 40 according to an embodiment of the present invention. In comparison with the wireless communication device 10 shown in FIG. 1, the wireless communication device 40 may further comprise a digital pre-distortion (DPD) circuit 160, where the DPD circuit 160 is coupled between the TX baseband circuit 110 and the delay skew compensation circuit 102. In particular, a nonlinear operation region of the SCPA 100 is another factor that causes the nonlinear distortion of the signal S_{OUT}, and the DPD circuit 160 is configured to perform a pre-distortion operation on the TX signal from the TX baseband circuit 110 such as the signal STX according to a nonlinear model, to generate a pre-distortion AM signal of the signal STX_{AM} such as a signal SD_{AM} and a pre-distortion PM signal of the signal STX_{PM} such as a signal SD_{PM}. More particularly, the AM circuit 120 may generate the signal VDD_{ENV} according to the signal SD_{AM} (e.g. the delay skew compensation circuit 102 may perform delay control on the signal SD_{AM} according to the estimation result τ_{CAL} to generate the signal SC_{AM}, and the AM circuit 120 may further generate the signal VDD_{ENV} according to the signal SC_{AM}), and the PM circuit 130 may generate the signal SRF_{PM} according to the signal SD_{PM}.

It should be noted that the AM-PM delay τ will not change in response to different signal swings, and thus the nonlinear distortion caused by the AM-PM delay τ will also not change. Different swings, however, reflect whether the SCPA 100 operates in the nonlinear operation region. Thus, the nonlinear distortion caused by the nonlinear operation region of the SCPA 100 may vary in response to different signal swings. In this embodiment, the gain of the SCPA 100 may be set to a first gain at the beginning, where the first gain may ensure that a signal swing of the signal S_{OUT} is small enough to prevent the SCPA 100 from entering the nonlinear operation region. When the gain of the SCPA 100 is set to the first gain, the delay skew calculation circuit 101 may generate the estimation result τ_{CAL}, according to a first detection result of the signal S_{OUT} (i.e. the IMD3 value obtained under a condition where the gain of the SCPA 100 is the first gain). As the nonlinear distortion occurs under the condition where the gain of the SCPA 100 is the first gain and caused by the AM-PM delay τ only, thus the delay skew calculation circuit 101 may estimate the AM-PM delay τ under a condition excluding the factor of the nonlinear operation region of the SCPA 100, and accordingly generate the estimation result τ_{CAL}. After the delay skew compensation circuit 102 compensates the signal VDD_{ENV} or the signal SRF_{PM} according to the estimation result τ_{CAL}, the gain of the SCPA 100 may be set to a second gain greater than the first gain, to make the signal swing of the signal S_{OUT} large enough to make the SCPA 100 enter the nonlinear operation region. As the delay skew compensation circuit 102 has already reduced or eliminated the AM-PM delay τ, the nonlinear distortion caused by the AM-PM delay τ may be reduced or eliminated, and the nonlinear distortion detected at this moment is caused by the nonlinear operation region of the SCPA 100 only. Thus, the DPD circuit 160 may control the nonlinear model according to a second detection result of the signal S_{OUT} (e.g. the nonlinear distortion value such as the IMD3 value obtained under the condition where the gain of the SCPA 100 is the second gain), to make the nonlinear model and the nonlinear distortion of the SCPA 100 cancel each other. As calibration and implementation of the nonlinear model of the DPD circuit 160 are well-known by those skilled in this art, related details are omitted here for brevity.

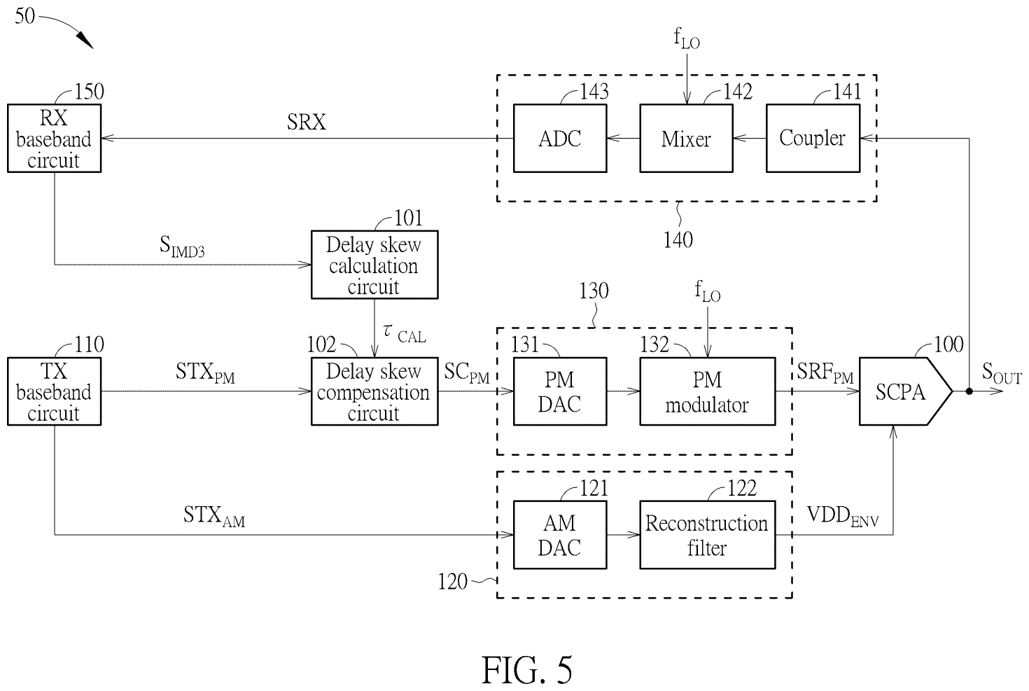

FIG. 5 is a diagram illustrating a wireless communication device 50 according to an embodiment of the present invention. It should be noted that a difference between the wireless communication device 50 shown in FIG. 5 and the wireless communication device 10 shown in FIG. 1 is that the delay skew compensation circuit 101 within the wireless communication device 50 is coupled between the TX baseband circuit 110 and the PM circuit 130, where the delay skew compensation circuit 102 may perform delay skew control on the signal STX_{PM} according to the estimation result τ_{CAL} to generate a compensated PM TX signal such as a signal SC_{PM}, and the PM circuit 130 may generate the signal SRF_{PM} according to the signal SC_{PM}. Under the architecture shown in FIG. 5, the PM DAC 131 within the PM circuit 130 may perform a digital-to-analog conversion on the signal SC_{PM} output from the delay skew compensation circuit 102, and the PM modulator 132 within the PM circuit 130 may perform an up-conversion on an output of the PM DAC 131 based on the LO frequency f_{LO} to generate the signal SRF_{PM}. In addition, the AM DAC 121 within the AM circuit 120 may perform digital-to-analog conversion on the signal STX_{AM}, and the reconstruction filter 122 within the AM circuit 120 may perform filtering on an output of the AM DAC 121 to generate the signal VDD_{ENV}. The remaining detailed operations of the wireless communication device 50 are the same as those of the wireless communication device 10 shown in FIG. 1, and will not be repeated here for brevity.

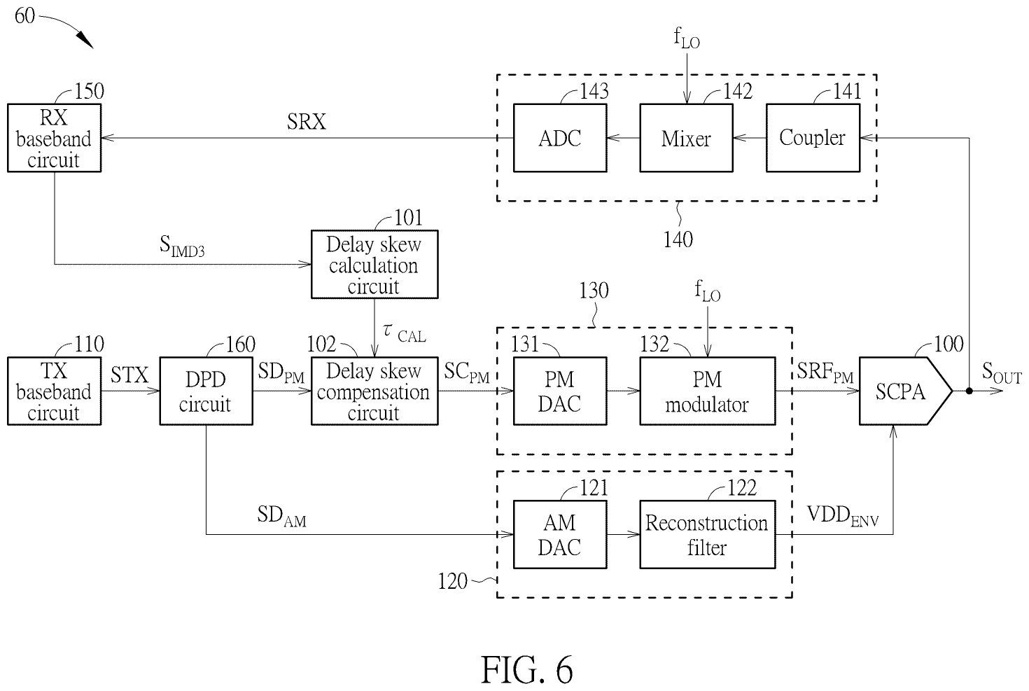

FIG. 6 is a diagram illustrating a wireless communication device 60 according to an embodiment of the present invention. In comparison with the wireless communication device 50 shown in FIG. 5, the wireless communication device 60 may further comprise the DPD circuit 160. It should be noted that the DPD circuit 160 within the wireless communication device 60 is the same as the DPD circuit 160 within the wireless communication device 40, and a difference between the wireless communication device 60 shown in FIG. 6 and the wireless communication device 40 shown in FIG. 4 may refer to the difference between the wireless communication device 10 shown in FIG. 1 and the wireless communication device 50 shown in FIG. 5; related details are omitted here for brevity.

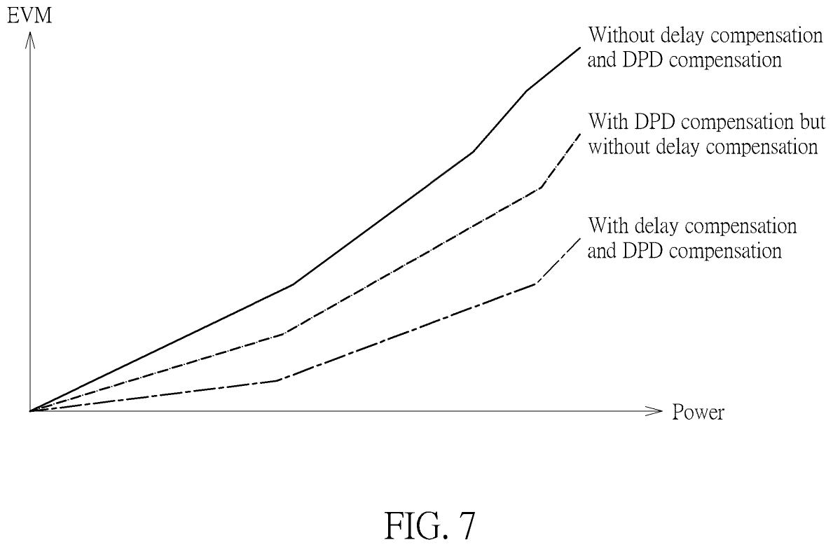

FIG. 7 is a diagram illustrating improvements in signal linearity by delay compensation and DPD according to an embodiment of the present invention, where a horizontal axis of FIG. 7 may represent output power of the SCPA 100 (e.g. power of the signal S_{OUT}), and a vertical axis of FIG. 7 may represent error vector magnitude (EVM) values under different power. More particularly, a higher EVM value means the nonlinear distortion is more severe. As shown in FIG. 7, when the DPD compensation and the AM-PM delay compensation mechanisms are not utilized, the signal S_{OUT} has the maximum EVM value (which means the linearity is the worst). When the DPD compensation mechanism is utilized but the AM-PM delay compensation mechanism is kept disabled, the EVM value of the signal S_{OUT} can be effectively reduced (which means the linearity is improved). When both the DPD compensation and the AM-PM delay compensation mechanisms are utilized, the EVM value of the signal S_{OUT} can be further reduced (which means the linearity is further improved). Thus, the linearity compensation mechanism provided by the present invention (e.g. performing the AM-PM delay compensation first and then performing the DPD compensation) can effectively improve the linearity of the signal S_{OUT}.

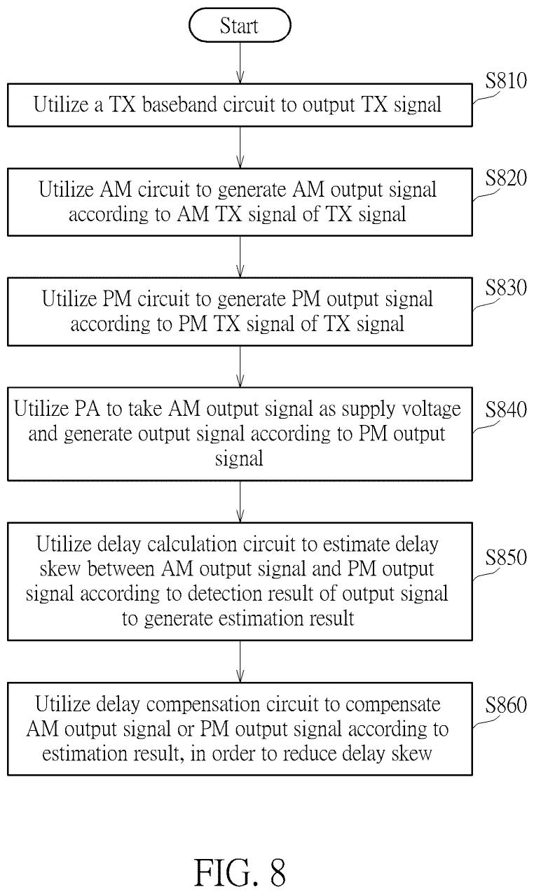

FIG. 8 is a diagram illustrating a working flow of a method for compensating nonlinear distortion of a wireless communication device (e.g. the wireless communication device 10, 40, 50 or 60) according to an embodiment of the present invention. It should be noted that the working flow shown in FIG. 8 is for illustrative purposes only, and is not meant to be a limitation of the present invention. For example, one or more steps may be added, deleted or modified in the working flow shown in FIG. 8. In addition, if a same result can be obtained, these steps do not have to be executed in the exact order shown in FIG. 8.

In Step S810, the wireless communication device may utilize a TX baseband circuit therein to output a TX signal.

In Step S820, the wireless communication device may utilize an AM circuit therein to generate an AM output signal according to an AM TX signal of the TX signal.

In Step S830, the wireless communication device may utilize a PM circuit therein to generate a PM output signal according to a PM TX signal of the TX signal.

In Step S840, the wireless communication device may utilize a PA therein to take the AM output signal as a supply voltage and generate an output signal according to the PM output signal.

In Step S850, the wireless communication device may utilize a delay calculation circuit therein to estimate a delay skew between the AM output signal and the PM output signal according to a detection result of the output signal to generate an estimation result.

In Step S860, the wireless communication device may utilize a delay compensation circuit therein to compensate the AM output signal or the PM output signal according to the estimation result, in order to reduce the delay skew.

To summarize, the wireless communication device and the associated method provided by the embodiments of the present invention can estimate the delay skew between the AM path and the PM path according to the IMD3 value of the output signal, and then accordingly perform compensation. More particularly, calibration associated with the DPD is performed after calibration of the delay skew between the AM path and the PM path is finished, to thereby ensure that a calibration process of the DPD is less likely to be affected by the delay skew between the AM path and the PM path. In addition, the embodiments of the present invention will not greatly increase additional costs. Thus, the present invention can improve performance of nonlinear distortion compensation without introducing any side effect or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wireless communication device, comprising:
a transmitting (TX) baseband circuit, configured to output a TX signal;
an amplitude modulation (AM) circuit, configured to generate an AM output signal according to an AM TX signal of the TX signal;
a phase modulation (PM) circuit, configured to generate a PM output signal according to a PM TX signal of the TX signal;
a power amplifier (PA), coupled to the AM circuit and the PM circuit, the PA configured to take the AM output signal as a supply voltage and generate an output signal according to the PM output signal;
a delay calculation circuit, configured to estimate a delay skew between the AM output signal and the PM output signal according to a detection result of the output signal to generate an estimation result; and
a delay compensation circuit, coupled to the TX baseband circuit and the delay calculation circuit, the delay compensation circuit configured to compensate the AM output signal or the PM output signal according to the estimation result, in order to reduce the delay skew.

2. The wireless communication device of claim 1, wherein the detection result comprises a third-order intermodulation distortion (IMD3) value of the output signal.

3. The wireless communication device of claim 1, further comprising:
a digital pre-distortion (DPD) circuit, coupled between the TX baseband circuit and the delay compensation circuit, the DPD circuit configured to perform a pre-distortion operation on the TX signal according to a nonlinear model, to generate a pre-distortion AM signal of the AM TX signal and a pre-distortion PM signal of the PM TX signal;
wherein the AM circuit generates the AM output signal according to the pre-distortion AM signal, and the PM circuit generates the PM output signal according to the pre-distortion PM signal.

4. The wireless communication device of claim 3, wherein:
when the PA is set to a first gain, the delay calculation circuit generates the estimation result according to a first detection result of the output signal; and
after the delay compensation circuit compensates the AM output signal or the PM output signal according to the estimation result, the PA is set to a second gain greater than the first gain, and the DPD circuit controls the nonlinear model according to a second detection result of the output signal to make the nonlinear model and nonlinear distortion of the PA cancel each other.

5. The wireless communication device of claim 1, further comprising:
a receiving (RX) circuit, coupled to the PA, the RX circuit configured to receive the output signal from the PA and generate an RX signal according to the output signal; and
an RX baseband circuit, coupled to the TX circuit and the delay calculation circuit, the RX baseband circuit configured to generate the detection result of the output signal according to the RX signal.

6. The wireless communication device of claim 1, wherein the delay compensation circuit is coupled between the TX baseband circuit and the AM circuit, the delay compensation circuit performs delay control on the AM TX signal according to the estimation result to generate a compensated AM TX signal, and the AM circuit generates the AM output signal according to the compensated AM TX signal.

7. The wireless communication device of claim 1, wherein the delay compensation circuit is coupled between the TX baseband circuit and the PM circuit, the delay compensation circuit performs delay control on the PM TX signal according to the estimation result to generate a compensated PM TX signal, and the PM circuit generates the PM output signal according to the compensated PM TX signal.

8. A method for compensating nonlinear distortion of a wireless communication device, comprising:
utilizing a transmitting (TX) baseband circuit of the wireless communication device to output a TX signal;
utilizing an amplitude modulation (AM) circuit of the wireless communication device to generate an AM output signal according to an AM TX signal of the TX signal;
utilizing a phase modulation (PM) circuit of the wireless communication device to generate a PM output signal according to a PM TX signal of the TX signal;
utilizing a power amplifier (PA) of the wireless communication device to take the AM output signal as a supply voltage and generate an output signal according to the PM output signal;
utilizing a delay calculation circuit of the wireless communication device to estimate a delay skew between the AM output signal and the PM output signal according to a detection result of the output signal to generate an estimation result; and
utilizing a delay compensation circuit of the wireless communication device to compensate the AM output signal or the PM output signal according to the estimation result, in order to reduce the delay skew.

9. The method of claim 8, wherein the detection result comprises a third-order intermodulation distortion (IMD3) value of the output signal.

10. The method of claim 8, further comprising:
utilizing a digital pre-distortion (DPD) circuit of the wireless communication device to perform a pre-distortion operation on the TX signal according to a nonlinear model, to generate a pre-distortion AM signal of the AM TX signal and a pre-distortion PM signal of the PM TX signal;
wherein the AM circuit generates the AM output signal according to the pre-distortion AM signal, and the PM circuit generates the PM output signal according to the pre-distortion PM signal.

11. The method of claim 10, wherein utilizing the delay calculation circuit of the wireless communication device to estimate the delay skew between the AM output signal and the PM output signal according to the detection result of the output signal to generate the estimation result comprises:
in response to the PA being set to a first gain, utilizing the delay calculation circuit to generate the estimation result according to a first detection result of the output signal; and
the method further comprises:
after the delay compensation circuit compensates the AM output signal or the PM output signal according to the estimation result, setting the PA to a second gain greater than the first gain, and utilizing the DPD circuit to control the nonlinear model according to a second detection result of the output signal to make the nonlinear model and nonlinear distortion of the PA cancel each other.

12. The method of claim 8, further comprising:
utilizing a receiving (RX) circuit of the wireless communication device to receive the output signal from the PA and generate an RX signal according to the output signal; and
utilizing an RX baseband circuit of the wireless communication device to generate the detection result of the output signal according to the RX signal.

13. The method of claim 8, wherein utilizing the delay compensation circuit of the wireless communication device to compensate the AM output signal or the PM output signal according to the estimation result in order to reduce the delay skew comprises:
utilizing the delay compensation circuit to perform delay control on the AM TX signal according to the estimation result to generate a compensated AM TX signal;
wherein the AM circuit generates the AM output signal according to the compensated AM TX signal.

14. The method of claim 8, wherein utilizing the delay compensation circuit of the wireless communication device to compensate the AM output signal or the PM output signal according to the estimation result in order to reduce the delay skew comprises:
utilizing the delay compensation circuit to perform delay control on the PM TX signal according to the estimation result to generate a compensated PM TX signal;
wherein the PM circuit generates the PM output signal according to the compensated PM TX signal.
